(19) United States
(12) Patent Application Publication
(10) Pub. No.: US 2026/0150247 A1
(43) Pub. Date: May 28, 2026

(54) PERSONAL COMPUTER HAVING PASSIVE COOLING, A PASSIVE COOLER, AND METHODS FOR PROVIDING THE SAME

(71) Applicant: ARCTIC (HK) Limited, Tsuen Wan (HK)

(72) Inventor: Magnus Huber, Jona (CH)

(73) Assignee: ARCTIC (HK) Limited, Tsuen Wan (HK)

(21) Appl. No.: 19/399,785

(22) Filed: Nov. 25, 2025

Related U.S. Application Data
(60) Provisional application No. 63/725,140, filed on Nov. 26, 2024.

(51) Int. Cl. H05K 7/20; G06F 1/20

(52) U.S. Cl. CPC H05K 7/20409; G06F 1/20; H05K 7/20127; H05K 7/20336; H05K 7/20509; G06F 2200/201

(57) ABSTRACT

A passively-cooled personal computer includes a housing, a motherboard disposed within the housing, a central processing unit (CPU) mounted on the motherboard, and a passive cooler thermally coupled to the CPU. The passive cooler includes a plurality of heat pipes and at least one set of stacked fins. The heat pipes extend through the fins and transport heat from the CPU to the fins. The set of stacked fins has a large cross-section in a horizontal plane and a small cross-section in a vertical plane.

### CROSS REFERENCE TO RELATED APPLICATIONS DATA

The present application claims priority to U.S. provisional patent application number 63/725,140, entitled PERSONAL COMPUTER HAVING PASSIVE COOLING AND METHOD FOR PROVIDING THE SAME, filed on Nov. 26, 2024, the entire contents of which are hereby incorporated by reference.

### BACKGROUND OF THE INVENTION

### Field of the Invention

The present disclosure relates to cooling systems for personal computers and more particularly, to a personal computer configuration that includes a passive cooling system for its components.

### Description of the Related Art

Typical computer systems include heat-generating components that require cooling. Central processing units (CPUs) and graphics processing units (GPUs) are the most common heat generating electrical components in a computing device. Computer cooling systems are used to remove the waste heat produced by CPUs and GPUs and other heat generating computer components.

In order to cool the CPU, most computers will include a mechanical cooler, such as a fan or water cooler or both. Such components take up space and make noise. As a result, personal computers are large and noisy, and not desirable for desktop usage.

Larger personal computers are often set on the floor next to a desk, requiring the routing and organization of wires to desktop video monitors, and other peripherals like speakers, keyboards and the like. To many, this is also undesirable.

Passive coolers that do not use a fan exist. FIG. 7 is a picture of a prior art cooler. In the picture, a typical passive cooler made for current CPUs from Intel and AMDis the NOCTUA NH-P1. As shown, it is mounted on an Intel CPU and a mini ITX board which is from a footprint point of view, almost no bigger than the cooler. The cooler does not relevantly leave the area of the mainboard. As the cross-section vertical to the airflow is not very large, the performance is rather unsatisfying despite the huge mass of over 1 kg. Note, this sits on top of the CPU within the PC. As the height of the cooler alone is 158 mm, the PC must sit on the floor or on the desk, where it will take up much space.

Another known passive PC solution can be seen in FIG. 8. This is a desktop of around 8-25cm in height where the case is built with extrusion heatsinks and the CPU is thermally connected with those heatsinks by heat pipes, not soldered but only fixed in a cavity by mounting plates on the CPU and heatsink side and the gaps filled with thermal grease. This comes with the advantage that it allows different CPU positions and the disadvantage of higher thermal resistance. Black fins are the aluminum extrusion profile. No heat pipes going through the fins.

FIG. 9 shows another version of a prior art device. Here, the CPU is connected to an extrusion heatsink (cooler) which serves as a part of the case and is placed mostly above the mainboard. Despite the large height, the performance is still poor. The first board on the left is a regular board. There may be heat pipes to the CPU. Because an extrusion cooler is a single piece, it is harder to distribute the heat.

FIGS. 10-11 show another example of a prior art passive computer cooler. As shown, this is a “tower” case. There is a large, stacked fin heat pipe heatsink mounted onto the CPU (and GPU in this case as well). This model is very thick and thus not suitable to be used underneath a desk. The cross-section vertical to the airflow around 160×200mm), but the thickness of the cooler in direction of the airflow very large, with around 250 mm.

Half of the heat sink is above the mother board, but it is a relatively small cross-section so the cooling effect is not as good even though it is monstrously large. About 60% of the cooler is still next to the motherboard, which creates poor heat removal performance.

Thus, there is a need for a new and improved personal computer that is passively cooled and takes up less space than prior art personal computers and cooler. Further, there is a need for a passively cooled personal computer that is configured for under desk mounting.

### SUMMARY OF THE INVENTION

According to embodiments of the present invention, a personal computer is provided that can be passively cooled (including very powerful office CPUs) and thus creates no noise, does not take space on or underneath the desk (on the floor), and offers USB and audio connectivity as well as the power button at a very convenient location (becomes especially inconvenient when the case is standing on the floor in combination with a stand-up desk, is cheap to manufacture and to ship (low volume and weight), has no moving parts and thus a far lower failure rate.

According to embodiments of the present invention, a personal computer is provided with a passive cooling system for cooling heat generating components, such as the CPU. According to embodiments, the CPU is mostly cooled through natural convection. According to embodiments, the cooling system has a cooler with a large cross section in the horizontal plane so that the air can flow vertically through it while making the size in the vertical plane relatively small.

According to embodiments of the present invention, the personal computer includes a small motherboard in the center of its housing, and a stacked fin heat pipe heatsink transporting heat from the CPU to the left and the right of the motherboard. Preferably, the heat pipe travels through the fins at a point between the bottom of the fins and the top plate, preferably at the center point therebetween. A space or gap above and below the heat pipes is provided for the flow of hot air. The fins should be sufficiently spaced.

According to embodiments of the present invention, the mother board is positioned to one side only and the heat pipes on the other side of the motherboard.

According to embodiments of the present invention, the fin area does not overlap the mainboard, but in other embodiments, it may overlap the mainboard.

According to embodiments of the present invention, at least more than half of the fin area is outside the mainboard area.

According to embodiments of the present invention, the personal computer has a very short depth and height, and is configured to be mounted under a desk. According to embodiments of the present invention, the size of the personal computer is preferably no more than 50 mm in height. According to embodiments of the present invention, the size of the personal computer is preferably no more than 180 mm in depth. According to embodiments of the present invention, the size of the personal computer is 536 mm length or smaller, 180 mm depth or smaller, and 50 mm height or smaller. Depth could be bigger or smaller and the skilled person will understand that other dimensions will work within the scope of the invention. For example, a thicker PC could be made longer or designed to be off to the side. The dimensions are preferably set for improved form function.

According to embodiments of the present invention, a passive cooler for a personal computer is provided. The cooler includes a stacked fin heat pipe heatsink for transporting heat away from a CPU. The heat pipe travels through the fins. The cooler preferably has a large cross section in the horizontal plane so that the air can flow vertically through it while making the size in the vertical plane relatively small.

According to embodiments of the present invention, a method of cooling a CPU includes providing passive cooler to be mounted or otherwise coupled to a CPU for heat transfer. The cooler includes a stacked fin heat pipe heatsink for transporting heat away from a CPU. The heat pipe travels through the fins. The cooler preferably has a large cross section in the horizontal plane so that the air can flow vertically through it while making the size in the vertical plane relatively small.

According to embodiments of the present invention, a method for cooling of a computer comprising steps of: providing at least one set of fins having a large cross section in the horizontal plan and a smaller cross section in the horizontal plane; providing a cool plate configured to be coupled in a heat conducting manner with the CPU; and providing a plurality of fluid containing heat pipes coupled with said cool plate and with said fins so as to transfer heat from said cool plate to said fins passively, without a pump.

According to embodiments of the present invention, the cooler may be designed so that the mother board can positioned to one side only.

According to embodiments of the present invention, at least more than half of the fin area is outside the mainboard area.

According to embodiments of the present invention, a passively-cooled personal computer is provided. The PC includes a housing, a motherboard disposed within the housing, a central processing unit (CPU) mounted on the motherboard, and a passive cooler. The passive cooler is thermally coupled to the CPU. The passive cooler includes a plurality of heat pipes and at least one set of stacked fins. The heat pipes extend through the fins and transport heat from the CPU to the fins. The fins having a large cross-section in a horizontal plane and a small cross-section in a vertical plane.

According to embodiments of the present invention, the stacked fins have total horizontal cross section of at least 240 cm².

According to embodiments of the present invention, the motherboard is positioned centrally within the housing, and the fins are positioned on both sides of the motherboard.

According to embodiments of the present invention, the motherboard is positioned on one side within the housing and the fins are positioned on the other sides of the motherboard.

According to embodiments of the present invention at least more than half of the fin area is outside an area occupied by the motherboard.

According to embodiments of the present invention, a top plate of the housing is configured to attach to an underside of a desk, the top plate providing a space above the fins for hot air to flow.

According to embodiments of the present invention, the heat pipes are positioned through the fins at a point between a bottom of the fins and a top plate, substantially at a center point therebetween, providing gaps above and below the heat pipes for airflow.

According to embodiments of the present invention, a perforated cover is positioned over the motherboard to allow natural airflow while protecting internal components.

According to embodiments of the present invention, a remote input/output panel is electrically coupled to the personal computer, the panel including a power button and at least one I/O jack, configured for mounting in a user-accessible location.

According to embodiments of the present invention, the fins are exposed to the environment from below and a rear of the housing to enable vertical airflow through the fins.

According to embodiments of the present invention, the heat pipes are flattened at a portion coupled to the cool plate for direct contact with the CPU.

According to embodiments of the present invention, at least more than half of the fin area is configured to be positioned outside an area occupied by a motherboard when installed in a personal computer.

According to embodiments of the present invention the heat pipes contain a fluid that undergoes phase change to transfer heat passively without a pump.

According to embodiments of the present invention, the fins are spaced sufficiently to allow natural convection airflow, and the heat pipes have a thickness of approximately 0.25 mm.

According to embodiments of the present invention, the method for passively cooling a CPU includes steps of providing a cool plate, a plurality of heat pipes coupled to the cool plate, and at least one set of stacked fins with the heat pipes extending through the fins; thermally coupling the cool plate to the CPU such that heat is transferred from the CPU to the fins by the heat pipes, wherein the fins have a large cross-section in a horizontal plane and a small cross-section in a vertical plane.

According to embodiments of the present invention, the CPU may positioned on a motherboard, the method further comprising a step of arranging the fins on opposite sides of the motherboard.

According to embodiments of the present invention, the at least more than half of the fin area is positioned outside an area occupied by a motherboard on which the CPU is mounted.

According to embodiments of the present invention, the at least one set of stacked fins has a horizontal cross section of at least 240 cm

According to embodiments of the present invention, the heat pipes may be positioned through the fins at a center point between a bottom of the fins and a top thereof, providing gaps for hot air flow.

According to embodiments of the present invention, the method includes exposing the fins to the environment to enable natural vertical airflow through the fins.

According to embodiments of the present invention, the heat transfer occurs via phase change of a fluid within the heat pipes without using a pump or fan.

According to embodiments of the present invention, the method includes a step of providing a remote input/output panel for user access, electrically coupled to a mother board on which the CPU.

According to embodiments of the present invention, the fins are spaced to allow sufficient airflow.

According to embodiments of the present invention, the method includes attaching a top plate above the fins to a desk underside, providing space for air dispersion.

### BRIEF DESCRIPTION OF DRAWINGS

Embodiments of the present invention are illustrated by way of example with reference to the accompanying drawings, which should not be construed to limit the present disclosure.

FIG. 1 is a rear-bottom perspective drawing of a personal computer having a passive cooling system according to embodiments of the present invention.

FIG. 2 is a rear-top perspective drawing of a personal computer having a passive cooling system according to embodiments of the present invention.

FIG. 3 is a bottom view of a cooler adapted to cool the CPU of a personal computer passively according to embodiments of the present invention.

FIG. 4 is a front-bottom perspective view of a cooler adapted to cool the CPU of a personal computer passively according to embodiments of the present invention.

FIG. 5 is a perspective view of a remote control and I/O panel for a personal computer according to embodiment of the present invention.

FIG. 6 is a block diagram of a personal computer according to embodiments of the present invention.

FIGS. 7-11 are renderings of prior art coolers for computers.

FIG. 12 is a front-bottom perspective view of a cooler adapted to cool the CPU of a personal computer passively having all the fins on one side of the CPU, according to embodiments of the present invention.

### DETAILED DESCRIPTION OF THE PREFERRED EMBODIMENTS

The following descriptions are presented to enable any personal skilled in the art to create and use apparatuses, systems and methods described herein.

According to embodiments of the present invention, provide herein is a novel personal computer having a passive cooler, a passive cooler for a personal computer, and a method for cooling a personal computer passively.

According to embodiments of the present invention, the cooler and personal computer are configured to be mounted under a table or desktop, and therefore, preferably have a large cross section in the horizontal plane to provide good vertical to the airflow, but relatively flat and has a small height. It is preferably that the width be much larger than the depth to prevent overlap with a user's legs.

According to embodiments of the present invention, the personal computer has a small motherboard.

According to embodiments of the present invention, the cooler has no fan, no pump and no moving parts.

According to embodiments of the present invention, the personal computer has a CPU that operates at 90 Watts or less, but the invention is not limited to low power CPUs.

According to embodiments, the cooler includes a relatively large blade (e.g., 536 mm length, 180 mm depth and 50 mm thickness). Length will typically be less important given the width of desks or tables, but the depth should ideally be small enough that it can be placed underneath the desk so that it does not overlap with the legs of the user. The thickness or height is ideally very small so that even if the user faces a situation where the legs overlap with the computer, he does not touch it.

According to embodiments of the invention, the personal computer comprises a small motherboard in the center and a stacked fin heat pipe heatsink for transporting the heat from the CPU to the fins left and the right of the motherboard. Although less preferred, the motherboard can be offset to the left side or the right side, but cooling is more efficient if the distance from the CPU to the end of the pipe is no longer than 30 cm.

According to some embodiments, the fin area can overlap the mainboard, but preferably, most of the fin area is outside the mainboard area in order to keep the mainboard area cool. Between the fins and the top plate (fixed to the desk from underneath), there should be a space provided for the hot air to flow off. The heat pipe goes through the fins.

Hot air travels vertically through the fins, up to the desk, and there, it will distribute. Very little air movement should be necessary to disperse the hot air from the computer/desk. It is an absolute fraction of the air flow that you get with a fan, that is why it needs to be so big and creates a massive footprint for a PC. But if you want to make it small, you need rather large fans.

Preferably, the fins are exposed to the environment. The fins preferably run in a direction from the front to the back, but could run from side to side, although this might create a less desirable heat path and could allow hot air to collect near the mother board.

The power button for the personal computer could be positioned in an appropriate place or provided with a remote. For example, a remote box could also have an extended power button with USB cables and maybe some other jacks but wired to the computer.

According to certain embodiments, heat pipes can be flattened at the bottom and touch the CPU directly. Preferably, the computer includes an APU that has the GPU integrated to make it easier to cool. The personal computer therefore is preferably an office PC or thin client.

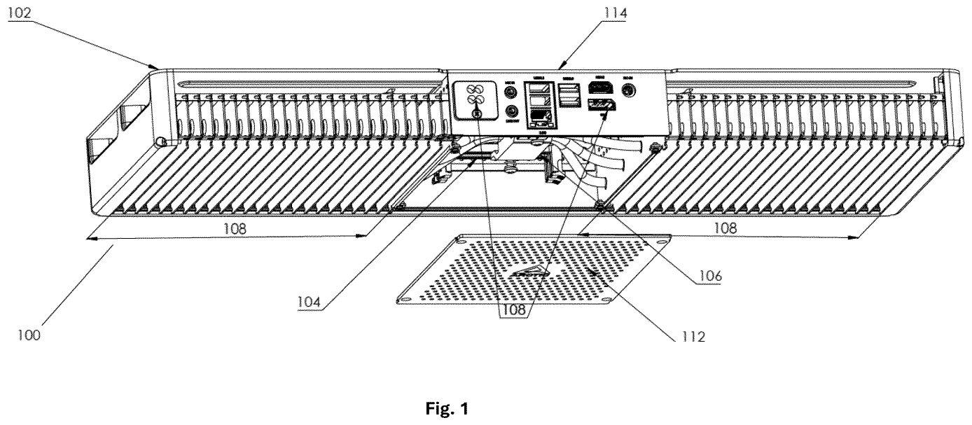

FIG. 1 illustrates an exemplary personal computer 100 having a passive cooler according to an embodiment of the present invention. Computer 100 has a housing 102 that holds a motherboard 104, which has a chipset (e.g., CPU) 106 requiring cooling. Fins 108 may be exposed from below and the back and are positioned on both sides of the CPU 106. Heat pipes 110 allow a coolant to flow through fins 108 and back to the CPU 106, thereby discharging energy to the fins 108, to the air. A perforated cover 112 is provided to cover the motherboard 104 and interior of the computer 100 while allowing natural air flow thereto. I/O connections 114 (e.g., HDMI, USB, AUX, Power, etc.) are provided near the motherboard 106 at the back of the computer 100.

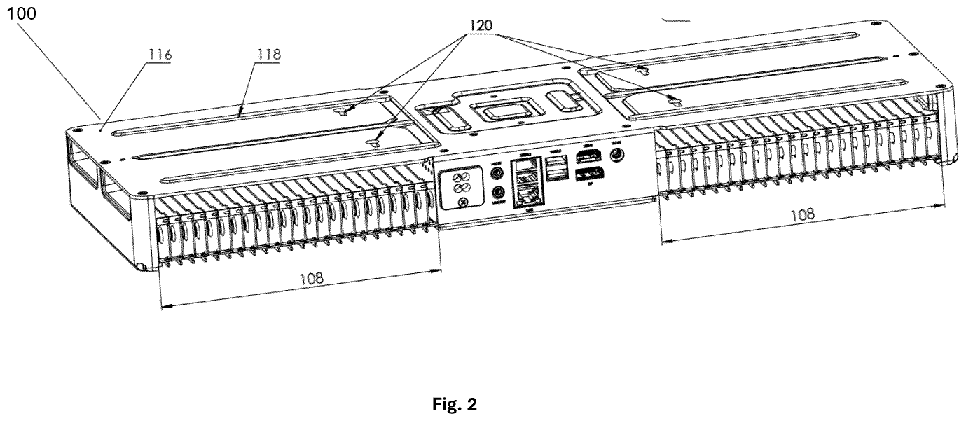

FIG. 2 shows another view of person computer 100. As shown, the top 116 of the frame 102 may include mechanical groove 118 and is configured to be attached to the bottom surface of a tabletop, counter or desk top via couplings 120 (e.g., openings to receive screw heads or bolts). The top plate 116 is preferably metal, such as, aluminum to conduct heat away from ancillary components, such as voltage regulators.

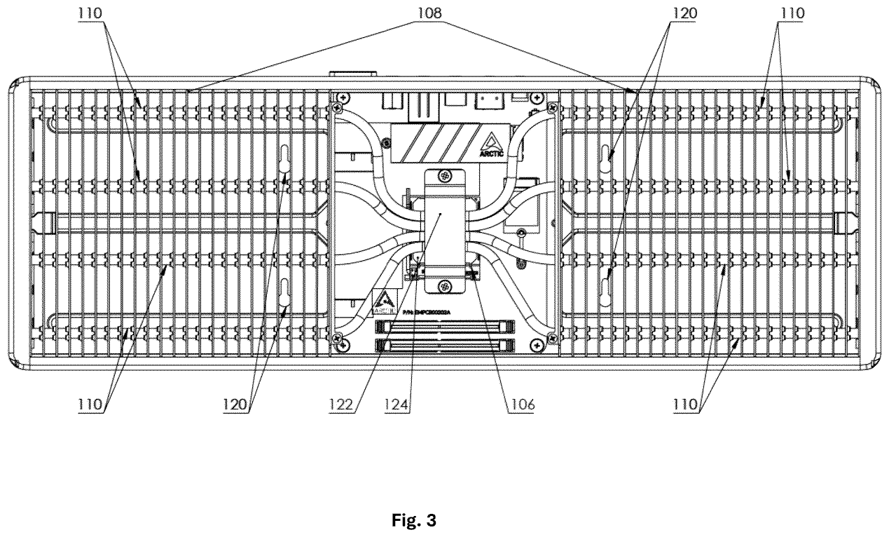

FIG. 3 shows a bottom view of the personal computer 100. As is clearly shown, the heat pipes 110 are brought together and flattened onto the CPU 106 and fixed thereto for good heat conduction. For example, copper pipes could be machined to be flat and directly coupled with the CPU for forming a good heat conductive connection therewith. Alternatively, a copper plate could be soldiered onto the top of the pipes for forming a good heat conductive connection. Here, a metal clip 122 secures the heat pipes 110 to the CPU to be cooled. The ends of the pipes 110 may be connected to form loops or may simply be capped. Any number of heat pipes may be used. The pipes should be designed to allow the warm water (or other fluid or coolant) to perform a phase change to pull the heat from the CPU 106 out to the fins to be cooled.

Preferably, the space within the pipes is only a small percentage filled with water while the remain space is vacuum. The water will pool under the CPU 106 and go through a phase change at a much lower temperature (e.g., 25 degree Centigrade) and steam will move out into the pipes 110 to be cooled by air and will condense and flow back the CPU area by gravity or capillary force. That is, water is vaporizing at the energy input, gas is distributed along the heat pipes and condensation where energy leaves the heat pipes.

The fins 108 should have adequate spacing to allow for good air flow so that the heat pipes 110 may be cooled. The heat pipes 110 are preferably copper and have a suitable thickness (e.g., 0.25 mm). If a copper plate is provided, it can be plated with a suitable, conductive material to provide strength or to reduce corrosion. For example, nickel-plated copper could be used. Couplings 120 can also be seen. Natural convection moves air vertically and cools the fins. There is also a minor heat exchange from the fins to the air or surrounding objects by radiation.

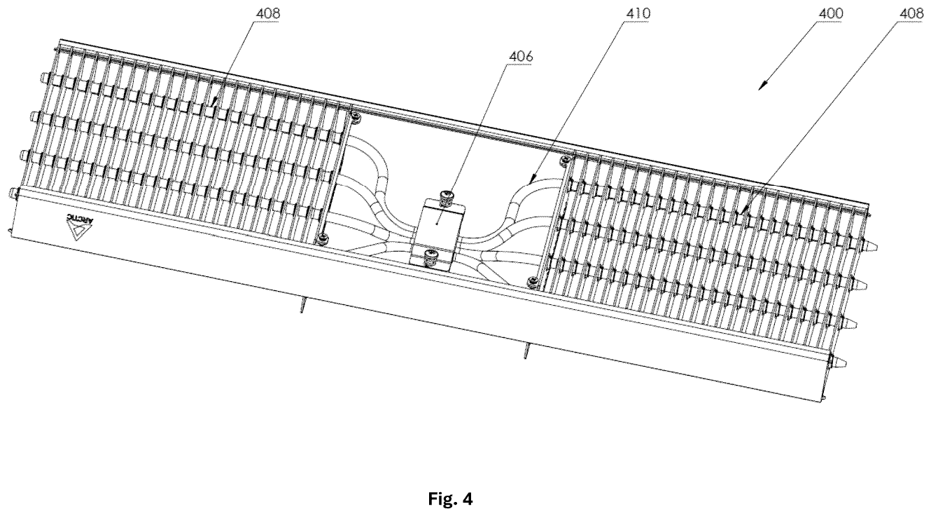

FIG. 4 shows bottom view of a cooler 400 according to an embodiment of the present invention. As shown, the cooler 400 includes two sets of fins 408 with a gap therebetween. A clip 406 is coupled with the heat pipes 410 and configured to secure the heat pipes 410 to a CPU (not shown) to conduct heat from a CPU or chip coupled thereto (e.g., see FIG. 3) and transfer the heat to the heat pipes 410, which in turn, transfer the heat to the fins 408 to the air passing therethrough. The heat pipes 410 are preferably designed similar to heat pipes 110, as described above.

According to embodiments, the cooler 400 includes a relatively large blade, for example, 536 mm in length (horizontal from right to left when facing the cooler, 180 mm in depth in the horizontal direction perpendicular to length, and 50 mm in thickness in vertical direction. The skilled person will understand long as the under-desk person computer 100 fits under the table without interfering with the user, the larger the size of the cooler, the better. For example, as width of 120 mm, a length of 300 mm and a thickness of 35 mm will not likely achieve adequate cooling. The cross section of the heatsink next to the board is preferably at least 200 mm by 120 mm, or equivalent horizontal cross section, to achieve a reasonable cooling performance. The skilled person will understand that an equivalent shaped cooler can be used so long as horizontal cross-section is large enough to cool the CPU without the need for moving parts, such as pumps or fans.

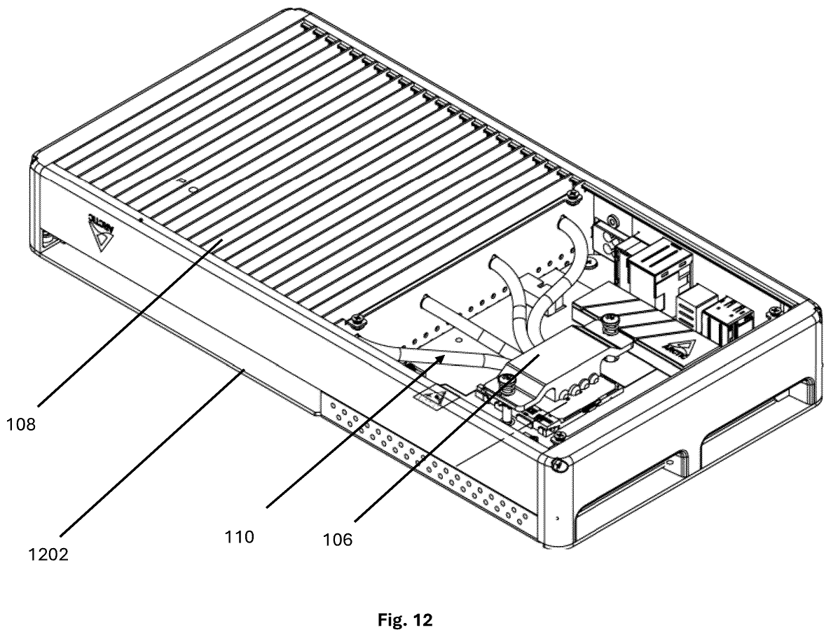

FIG. 12 shows an embodiment where the cooler 1208 has fins 108 on only one side of the clip 106 coupled with the heat pipes 110. The skilled person will understand that an equivalent shaped cooler can be used so long as horizontal cross-section is large enough to cool the CPU without the need for moving parts, such as pumps or fans.

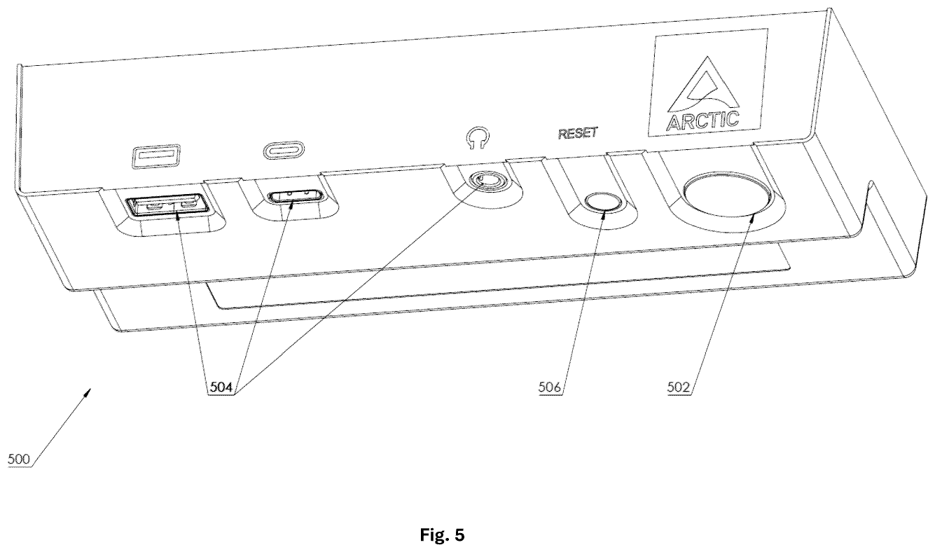

FIG. 5 shows an exemplary remote 500 for the computer 100 which may be connected by wire, wireless connection (e.g., Bluetooth dongle, etc.). Preferably, the remote includes at least a power button 502, and some I/O jacks 504, and is configured to be mounted in a location convenient to the user, such as below a desk under the left front corner, so that it is easy to access for a user. The remote may include any number of I/O interfaces and could include a reset button 506 as well.

As the computer is installed underneath the desk, a front panel 500 is connected to the PC in order to turn it ON or OFF and also, to provide a convenient interface since the I/O jacks of the PC are likely inconvenient to access on a daily basis. This panel is fixed by screws underneath the desk and flush with the edge of the table facing the user, typically arranged either on the left or the right side of the table. It offers a power and reset button, a power LED, and audio jack for headphones and microphones, a USB A and a USB C socket.

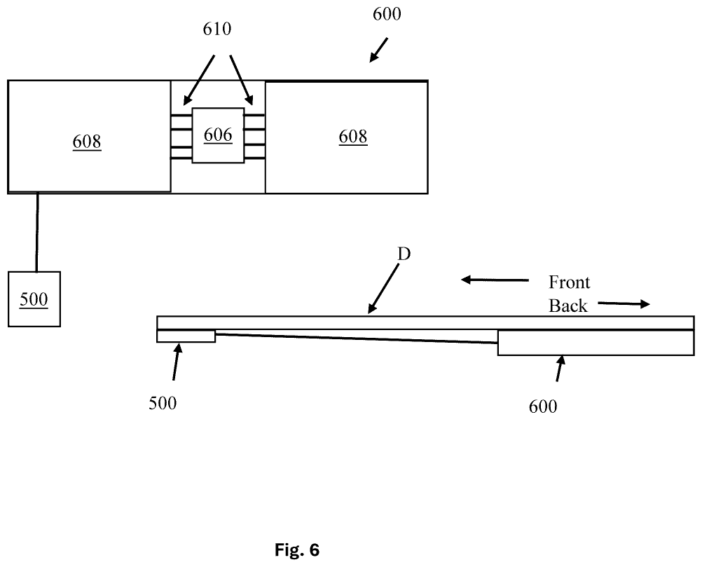

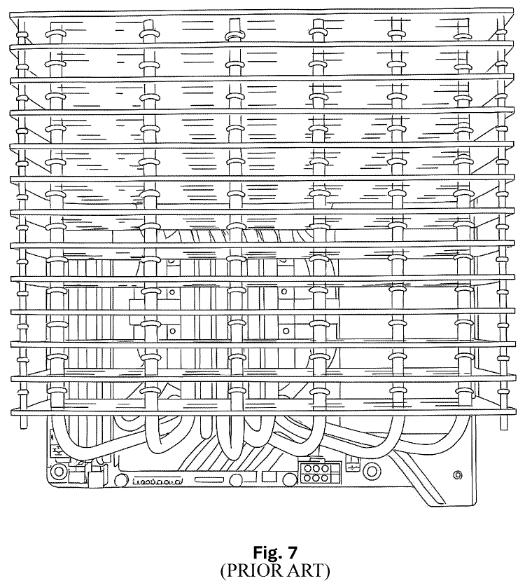

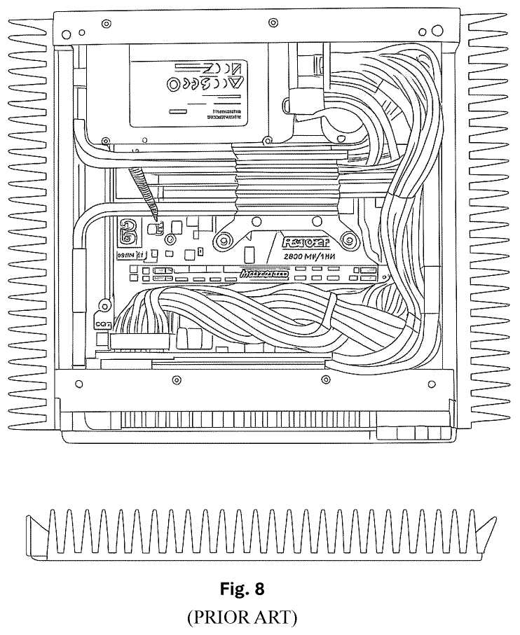

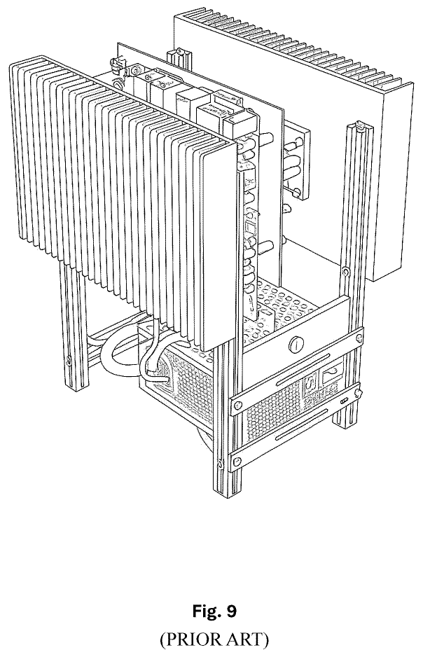

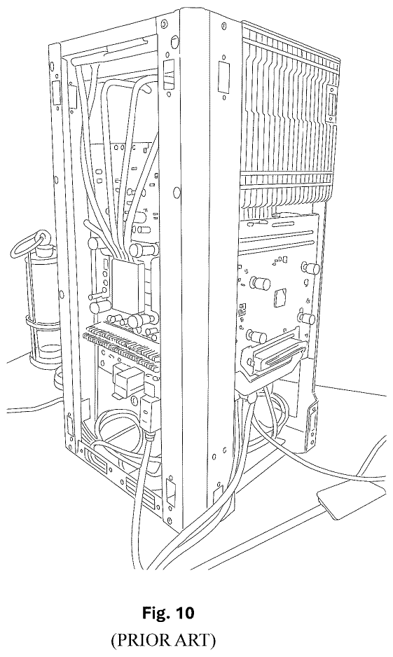

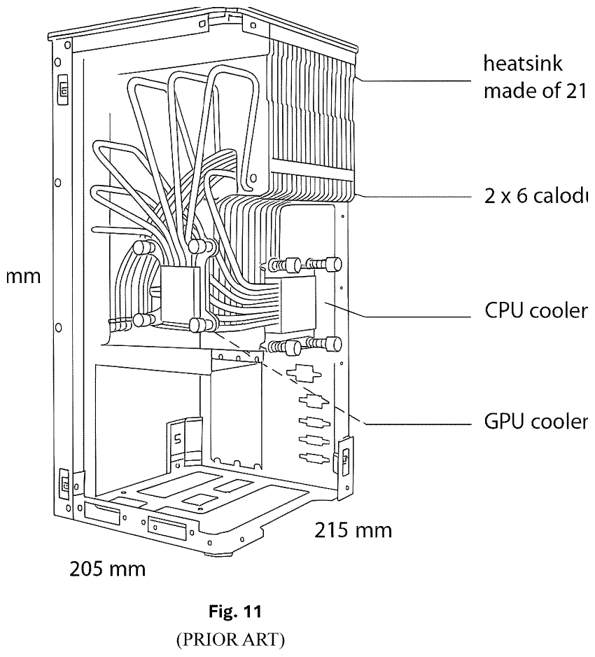

FIGS. 6A and 6B are simplified block diagrams of a computer having a passive cooler according to embodiments of the presentation invention. FIG. 6A is a simple top view and shows the computer 600 includes a CPU 606 to be cooled. Heat pipes 610 connect the CPU 606 to the fins 608 in a heat conducting manner. For example, as described above, heat pipes can deliver fluid between a cool plate and the fins to move hot fluid from the cool plate, which is mounted on the CPU, to the fins. Computer 600 may be electronically coupled with a remote 500.

FIG. 6B shows a side view showing the computer 600 and remote mounted to a desktop D and electronically coupled with the remote 500.

In this description, numerous details are set forth for the purpose of explanation. However, one of ordinary skill in the art will realize that the invention may be practiced without the use of these specific details. In other instances, well-known structures and processes are shown in block diagram form in order not to obscure the description of the invention with unnecessary detail. Thus, the present disclosure is not intended to be limited to the embodiments shown but is to be accorded the widest scope consistent with the principles and features disclosed herein.

In describing exemplary embodiments, specific terminology is used for the sake of clarity. For purposes of description, each specific term is intended to at least include all technical and functional equivalents that operate in a similar manner to accomplish a similar purpose. Additionally, in some instances where a particular exemplary embodiment includes a plurality of system elements, device components or method steps, those elements, components or steps may be replaced with a single element, component or step. Likewise, a single element, component or step may be replaced with a plurality of elements, components or steps that serve the same purpose. Moreover, while exemplary embodiments have been shown and described with references to particular embodiments thereof, those of ordinary skill in the art will understand that various substitutions and alterations in form and detail may be made therein without departing from the scope of the invention.

For example, the figures show the motherboard being positioned between two sets of fins. According to embodiments of the present invention, the mother board may be positioned to one side only and the heat pipes on the other side of the motherboard. In other words, the heat sink is next to the mainboard. The skilled person will understand as long as the heat sink's cross section for air vertically flowing through is large enough, such a configuration will achieve adequate cooling.

Exemplary dimensions and materials are described herein. The skilled person will understand that the dimensions and materials may be altered while achieving the same effects described herein.

Further still, other embodiments, functions and advantages are also within the scope of the invention.

What is claimed is:

1. A passively-cooled personal computer comprising:
a housing;
a motherboard disposed within the housing;
a central processing unit (CPU) mounted on the motherboard; and
a passive cooler thermally coupled to the CPU, the passive cooler including a plurality of heat pipes and at least one set of stacked fins, wherein the heat pipes extend through the fins and transport heat from the CPU to the fins, wherein the at least one set of stacked fins has a large cross-section in a horizontal plane and a small cross-section in a vertical plane.

2. The personal computer of claim 1, wherein the at least one set of stacked fins has a horizontal cross section of at least 240 cm².

3. The personal computer of claim 1, wherein the motherboard is positioned centrally within the housing, and the fins are positioned on both sides of the motherboard.

4. The personal computer of claim 1, wherein the motherboard is positioned on one side within the housing and the fins are positioned on the other sides of the motherboard.

5. The personal computer of claim 1, wherein at least more than half of the fin area is outside an area occupied by the motherboard.

6. The personal computer of claim 1, further comprising a top plate configured to attach to an underside of a desk, the top plate providing a space above the fins for hot air to flow.

7. The personal computer of claim 1, wherein the heat pipes are positioned through the fins at a point between a bottom of the fins and a top plate, substantially at a center point therebetween, providing gaps above and below the heat pipes for airflow.

8. The personal computer of claim 1, further comprising a perforated cover over the motherboard to allow natural airflow while protecting internal components.

9. The personal computer of claim 1, further comprising a remote input/output panel electrically coupled to the personal computer, the panel including a power button and at least one I/O jack, configured for mounting in a user-accessible location.

10. The personal computer of claim 1, wherein the fins are exposed to the environment from below and a rear of the housing to enable vertical airflow through the fins.

11. The personal computer of claim 1, wherein the passive cooler has no moving parts.

12. A passive cooler for cooling a central processing unit (CPU) comprising:
a cool plate thermally coupled to the CPU;
a plurality of heat pipes coupled to the cool plate; and
at least one set of stacked fins, wherein the heat pipes extend through the fins and transport heat from the cool plate to the fins, wherein the at least one set of stacked fins has a large cross-section in a horizontal plane and a small cross-section in a vertical plane.

13. The passive cooler of claim 12, wherein the fins are arranged in two sets with a gap therebetween to accommodate a motherboard.

14. The passive cooler of claim 12, wherein the fins are arranged in a set and configured to couple with the CPU positioned on a motherboard to one side of the fins.

15. The passive cooler of claim 12, wherein the heat pipes are flattened at a portion coupled to the cool plate for direct contact with the CPU.

16. The passive cooler of claim 12, wherein at least more than half of the fin area is configured to be positioned outside an area occupied by a motherboard when installed in a personal computer.

17. The passive cooler of claim 12, wherein the heat pipes are positioned through the fins at a point substantially centered between a bottom of the fins and a top thereof, providing gaps for airflow.

18. The passive cooler of claim 12, wherein the heat pipes contain a fluid that undergoes phase change to transfer heat passively without a pump.

19. The passive cooler of claim 12, wherein the fins are spaced sufficiently to allow natural convection airflow, and the heat pipes have a thickness of approximately 0.25 mm.

20. The passive cooler of claim 12, wherein the at least one set of stacked fins has a horizontal cross section of at least 240 cm².

21. A method for passively cooling a central processing unit (CPU) comprising steps of:
providing a cool plate, a plurality of heat pipes coupled to the cool plate, and at least one set of stacked fins with the heat pipes extending through the fins;
thermally coupling the cool plate to the CPU such that heat is transferred from the CPU to the fins by the heat pipes, wherein the at least one set of stacked fins has a large cross-section in a horizontal plane and a small cross-section in a vertical plane.

22. The method of claim 21, wherein the CPU is positioned on a motherboard, the method further comprising a step of arranging the fins on opposite sides of the motherboard.

23. The method of claim 21, wherein at least more than half of the fin area is positioned outside an area occupied by a motherboard on which the CPU is mounted.

24. The method of claim 21, wherein the at least one set of stacked fins has a horizontal cross section of at least 240 cm².

25. The method of claim 21, wherein the heat pipes are positioned through the fins at a center point between a bottom of the fins and a top thereof, providing gaps for hot air flow.

26. The method of claim 21, further comprising a step of exposing the fins to the environment to enable natural vertical airflow through the fins.

27. The method of claim 21, wherein the heat transfer occurs via phase change of a fluid within the heat pipes without using a pump or fan.

28. The method of claim 21, further comprising a step of providing a remote input/output panel for user access, electrically coupled to a mother board on which the CPU.

29. The method of claim 21, wherein the fins are spaced to allow sufficient airflow.

30. The method of claim 21, further comprising a step of attaching a top plate above the fins to a desk underside, providing space for air dispersion.
